(19) United States
(12) Patent Application Publication
(10) Pub. No.: US 2009/0135109 A1
(43) Pub. Date: May 28, 2009

(54) ORGANIC EL ELEMENT, ORGANIC EL DISPLAY DEVICE, AND METHODS OF MANUFACTURING THE SAME

(75) Inventors: Tadahiro Ohmi, Miyagi (JP); Tetsuya Goto, Miyagi (JP); Takaaki Matsuoka, Tokyo (JP)

Correspondence Address: PEARNE & GORDON LLP, 1801 EAST 9TH STREET, SUITE 1200, CLEVELAND, OH, 44114-3108, US

(73) Assignees: NATIONAL UNIVERSITY CORPORATION TOHOKU UNIVERSITY, Miyagi (JP); TOKYO ELECTRON LIMITED, Tokyo (JP)

(21) Appl. No.: 12/273,745

(22) Filed: Nov. 19, 2008

(30) Foreign Application Priority Data
Nov. 22, 2007 (JP) 2007-303205

(51) Int. Cl. H01J 1/62; C23C 14/35; G09G 3/30

(52) U.S. Cl. 345/76; 313/504; 204/192.17

(57) ABSTRACT

In an organic EL element having a transparent conductive electrode and a cathode opposed to the transparent conductive electrode, the cathode includes a film of a rare earth element that can be sputtered. The film of the rare earth element having a low work function, for example, a LaB₆ film, can be formed uniformly over a wide area on an electron injection layer by a rotary magnet sputtering apparatus.

This application is based upon and claims the benefit of priority from Japanese Patent Application No. 2007-303205, filed on Nov. 22, 2007, the disclosure of which is incorporated herein in its entirety by reference.

### TECHNICAL FIELD

This invention relates to a light emitting element such as an organic EL element, an organic EL display device including a plurality of light emitting elements, and methods of manufacturing them.

### BACKGROUND ART

In recent years, self-luminous organic EL display devices have been actively studied as display devices that can achieve high brightness while being of the thin type. Organic EL elements each have a structure in which an organic layer serving as a light emitting layer is interposed between opposing electrodes, and the light emission is controlled by on/off of the current to the electrodes of the respective organic EL elements, thereby forming a display device. The display devices are classified into a passive matrix type and an active matrix type. The former is used as a backlight or a relatively low definition display device and the latter is used as a relatively high definition display device such as a television or a monitor. Further, the passive matrix type and the active matrix type each include a bottom emission type and a top emission type.

In organic EL elements forming such organic EL display devices, a large problem is that the lifetime of an organic layer serving as a light emitting layer is short. Although the light emission time has been increasing through various studies in recent years, the current element lifetime is still short when used, for example, for a television or a monitor, wherein the brightness is reduced by half in 2000 to 3000 hours in the case of continuous lighting. As a reason for the short element lifetime, invasion of moisture into the organic layer serving as the light emitting layer or thermal destruction due to heating after formation of the organic layer or due to heat generation of the element is notable, and various improvements have been proposed.

Japanese Unexamined Patent Application Publication (JP-A) No. 2005-019338 (Patent Document 1) discloses an organic EL element having a structure in which a transparent conductive electrode, an electron transport layer, an organic EL light emitting layer, a hole transport layer, and a counter electrode are laminated in this order and proposes that the counter electrode be made of a conductive material such as Co or Ni having a work function of 4 eV to 6 eV and the transparent conductive electrode be made of ITO having a work function of 4.8 eV. With this structure, it is possible to match work functions between the transparent conductive electrode and the electron transport layer and to match work functions between the hole transport layer and the counter electrode. As a result, with this structure, it is possible to improve the light emission efficiency and to obtain an organic EL element having a long lifetime.

In addition, Patent Document 1 discloses that the lifetime of the organic EL element can be further increased by providing an insulating protective layer and a heat dissipating layer.

### DISCLOSURE OF THE INVENTION

The organic EL element described in Patent Document 1 has a structural feature such that it does not require an electron injection layer or a hole injection layer. However, this conversely means that it is not applicable to a normal organic EL element having an electron injection layer and a hole injection layer. That is, the normal organic EL element has a structure in which a hole injection layer, a hole transport layer, an organic EL light emitting layer, an electron transport layer, an electron injection layer, and a counter electrode are stacked in this order on a transparent conductive electrode. However, the structure disclosed in Patent Document 1 cannot be applied to such a normal-structure organic EL element.

On the other hand, according to the study by the present inventors, if the counter electrode (i.e. the cathode) has a two-layer structure comprising a Li layer and an Ag layer and the Li layer having a work function of 2.9 eV is disposed so as to be in contact with the electron injection layer having a work function of about 3.0 eV in the normal-structure organic EL element described above, it is possible to obtain a long-lifetime organic EL element.

However, when Li is used as a material of the counter electrode, a Li layer forming method is limited to deposition of Li and cannot employ sputtering using a Li target. With this limitation of the Li layer forming method to the deposition, various drawbacks as follows cannot be avoided. That is, when Li is used as a deposition source, a film tends to be formed on the surface of Li as a deposition material and thus the start of evaporation is unstable, and this results in a problem that the storage and handling of the deposition material require much labor. Further, when producing lithium hydroxide in the atmosphere, the handling requires care. Moreover, evaporation of Li is carried out while it is placed on a boat, but deterioration of the molten material proceeds even in such evaporation of Li and thus the film forming rate is unstable and, further, there is also a case where a thin film after the film formation reacts with residual moisture/oxygen/nitrogen in a chamber so as to be deteriorated. This means that when use is made of Li having a work function matching an electron injection layer as described above, it is not possible to form a Li layer having a uniform thickness over a wide area (2 m to 9 m square).

On the other hand, also in organic EL display devices each formed by organic EL elements, an increase in area has been demanded. Therefore, it is expected that there will occur a case where organic EL display devices including Li layers cannot respond to the demand for the increase in area of display device.

It is therefore an object of this invention to provide an organic EL element and an organic EL display device, that can respond to the demand for the increase in area by improving a material of a counter electrode, i.e. a cathode.

It is another object of this invention to provide an organic EL element and an organic EL display device, that include an electrode formed uniformly over a large area by sputtering.

According to a first aspect of this invention, there is provided an organic EL element, comprising:

a transparent conductive electrode;

a counter electrode opposed to the transparent conductive electrode; and

an organic layer including an organic EL light emitting layer and provided between the transparent conductive electrode and the counter electrode,

wherein the counter electrode includes a first layer of boride of a rare earth element and a second layer of a conductive and reflective material, the first layer being located on the side of the organic layer.

In the first aspect, the boride of the rare earth element may be LaB₆ or LaB₄.

In the first aspect, the organic layer may include an electron injection layer at a portion contacting with the first layer of boride of the rare earth element, the electron injection layer having a work function of 2.5 eV to 3.0 eV.

In the first aspect, the material of the second layer may have a reflectivity of more than 90%.

In the first aspect, the material of the second layer may include Ag.

In the first aspect, the first layer may have a thickness not smaller than 0.4 nm and smaller than 10 nm. Preferably, the thickness of the first layer is 0.5 nm to 5 nm.

According to a second aspect of this invention, there is provided an organic EL element, comprising:

an anode electrode;

a cathode electrode opposed to the anode electrode; and

an organic layer including an organic EL light emitting layer and provided between the anode electrode and the cathode electrode,

wherein the cathode electrode includes a layer of boride of a rare earth element having a thickness of more than 0.4 nm and less than 10 nm.

According to a third aspect of this invention, there is provided a method of manufacturing a light emitting element including a transparent conductive electrode formed on a transparent substrate, an organic layer including an organic EL light emitting layer and formed on the transparent conductive electrode, and a counter electrode formed on the organic layer, comprising:

upon forming the counter electrode, setting a target containing boride of a rare earth element in a sputtering apparatus having a rotary magnet, and

sputtering the target while rotating the rotary magnet, thereby forming a layer of boride of the rare earth element.

In the third aspect, the target may comprise LaB₆.

In the third aspect, the method further may comprise forming an Ag film by sputtering after forming the layer of boride of the rare earth element, thereby forming the counter electrode.

In the third aspect, the layer of boride of the rare earth element may have a thickness not smaller than 0.4 nm and smaller than 10 nm. As described in the first aspect, the upper limit and the lower limit have the critical significance.

According to a fourth aspect of this invention, there is provided an organic EL display device, comprising:

a plurality of gate lines and a plurality of signal lines arranged in a matrix;

switching elements provided at intersections of the gate lines and the signal lines; and

a plurality of organic EL elements selectively driven by the switching elements,

wherein each of the organic EL elements includes;

a transparent conductive electrode,

a counter electrode opposed to the transparent conductive electrode and including a first layer of boride of a rare earth element and a second layer of a conductive and reflective material, and

an organic layer provided between the transparent conductive electrode and the counter electrode, the first layer of the counter electrode being located on the side of the organic layer.

In the fourth aspect, the organic layer may include an electron injection layer at a portion contacting with the first layer of boride of the rare earth element, the electron injection layer having a work function of 2.5 eV to 3.0 eV.

In the fourth aspect, the boride of the rare earth element may be LaB₆ or LaB₄.

In the fourth aspect, the material of the second layer may have a reflectivity of more than 90%.

In the fourth aspect, the material of the second layer may include Ag.

In the fourth aspect, the first layer may have a thickness not smaller than 0.4 nm and smaller than 10 nm. Preferably, the thickness of the first layer is 0.5 nm to 5 nm. As described in the first aspect, the upper limit and the lower limit have the critical significance.

According to a fifth aspect of this invention, there is provided an organic EL display device, comprising:

a plurality of gate lines and a plurality of signal lines arranged in a matrix;

switching elements provided at intersections of the gate lines and the signal lines; and

a plurality of organic EL elements selectively driven by the switching elements,

wherein each of the organic EL elements includes;

an anode electrode;

a cathode electrode opposed to the anode electrode including a layer of boride of a rare earth element that has a thickness of more than 0.4 nm and less than 10 nm; and

an organic layer including an organic EL light emitting layer and provided between the anode electrode and the cathode electrode.

According to this invention, a cathode formed on an organic layer includes a film of a rare earth element, so that the film can be formed uniformly over a wide area and thus a large-area organic EL display device can be obtained.

### BRIEF DESCRIPTION OF THE DRAWINGS

FIG. 1 is a sectional view illustrating the structure of a bottom emission type passive display element according to a first embodiment of this invention;

FIG. 2 is a diagram for explaining a rotary magnet sputtering apparatus for use in forming a cathode of an organic EL element according to this invention;

FIG. 3 is a sectional view illustrating part of pixels of a bottom emission type passive matrix organic EL display device according to a second embodiment of this invention;

FIG. 4 is a sectional view illustrating part of pixels of a bottom emission type active matrix organic EL display device according to a third embodiment of this invention; and

FIG. 5 is a sectional view illustrating part of pixels of a bottom emission type active matrix organic EL display device according to a fourth embodiment of this invention.

### DESCRIPTION OF THE EXEMPLARY EMBODIMENTS

Hereinbelow, embodiments of this invention will be described with reference to the drawings.

### First Embodiment

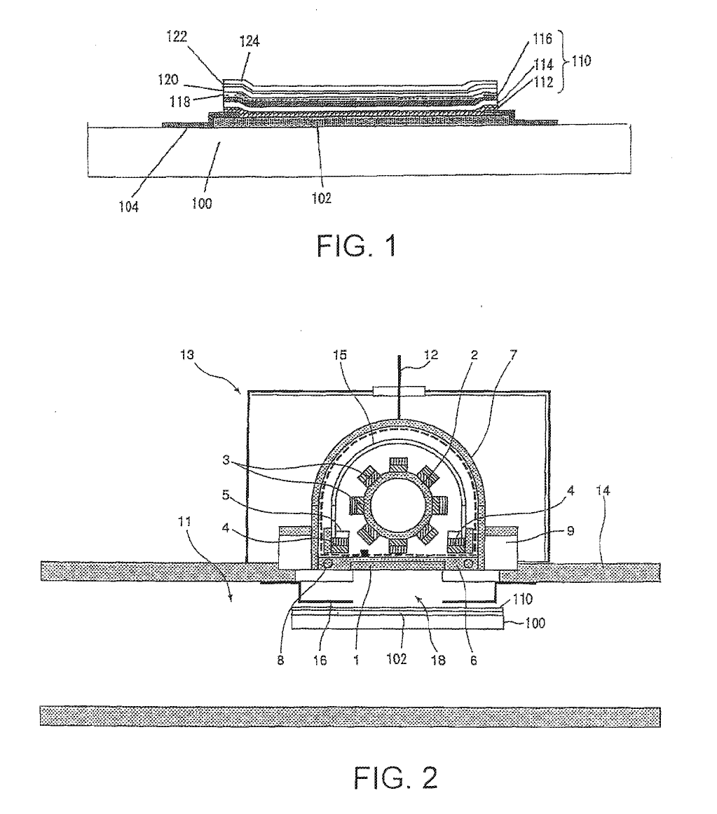

Referring to FIG. 1, a description will be given of an organic EL element according to the first embodiment of this invention. FIG. 1 is a sectional view illustrating the structure of a bottom emission type passive organic EL element. The illustrated organic EL element comprises a transparent substrate 100, a transparent conductive electrode, that is an anode electrode, 102 of ITO or the like formed on the transparent substrate 100, and an insulating film 104 of Si₃N₄ or the like formed so as to partly cover the transparent conductive electrode 102.

Further, the organic EL element of FIG. 1 has an organic layer 110 formed on the transparent conductive electrode 102. The illustrated organic layer 110 has a structure in which a hole injection layer 112, a hole transport layer 114, an organic EL light emitting layer (hereinafter simply referred to as a “light emitting layer”) 116, an electron transport layer 118, and an electron injection layer 120 are stacked in this order on the transparent conductive electrode 102.

Further, a cathode portion comprising a first cathode 122 and a second cathode 124 is mounted on the organic layer 110. Herein, the first electrode 122 is a film of a boride of a rare earth element with a relatively low work function, such as LaB₆, formed by sputtering, while, the second cathode 124 is made of an electrically conductive and light-reflective material, preferably having a reflectivity of more than 90%, such asAg orAl. In this case, Ag is used as a material of the second cathode 124. Although there are other rare earth element borides, such as LaB₄, YbB₆, GaB₆, and CeB₆, each usable as the first cathode 122, the following description will be given of only a case where LaB₆ is used.

Specifically, as the transparent substrate 100, use can be made of a material adapted to transmit light emitted from the light emitting layer 116 and a glass substrate is used in this embodiment.

For reducing a work function of a surface contacting the organic layer 110 to improve the efficiency of electron injection into the element, LaB₆ having a low work function of about 2.6 eV to 2.8 eV is used as the first cathode 122 and is deposited by way of sputtering using a later-described rotary magnet sputtering apparatus to a thickness of 1 nm to 2 nm in this embodiment.

Generally in the present invention, LaB₆ (the first electrode 122: the layer of boride of the rare earth element) has a thickness not smaller than 0.4 nm and smaller than 10 nm. Preferably, the layer of boride of the rare earth element has a thickness of 0.5 nm to 5 nm.

Herein, description will be made of critical significance regarding the upper limit and the lower limit of the thickness of the layer of boride of the rare earth element.

For example, Japanese Unexamined Patent Application Publication (JP-A) No. 2-234394 discloses a cathode made solely of metal-boride such as LaB₆ and that has a thickness between 10 and 2000 nm. However, in this publication, LaB₆ alone is used as the cathode. Specifically, in the examples disclosed in this publication, a transparent substrate comprises a glass substrate with an ITO electrode formed thereon as an anode. With this structure, light is emitted from the transparent substrate and the LaB₆ cathode simply blocks the light.

On the other hand, according to the embodiment of this invention, LaB₆ is used as a first cathode while an electrically conductive and light-reflective material such as Ag is used as a second cathode. Generated light is reflected by Ag back to the substrate and emitted out through the transparent substrate. Therefore, the light emission efficiency is increased to nearly twice. If the thickness of LaB₆ falls within a range between 10 and 2000 nm in the above-mentioned structure, emitted light directed towards Ag is absorbed and, further, the reflected light is absorbed so that the reflection efficiency is significantly decreased. In order to achieve the reflectance of more than 80%, preferably more than 90%, for the visible light of 550 nm in wavelength, the thickness of LaB₆ film must be smaller than 10 nm. The lower limit of the thickness is 0.4 nm (corresponding to the particle size of the LaB₆ crystal grains).

In view of the above-mentioned reasons, the upper limit and the lower limit of the thickness of the layer of boride of the rare earth element are selected so that the thickness of LaB₆ is not smaller than 0.4 nm and smaller than 10 nm, preferably 0.5 nm to 5 nm. Thus, the upper limit and the lower limit have critical significance.

An Ag film as the second cathode 124 on the first cathode 122 made of LaB₆ is also formed using the rotary magnet sputtering apparatus like the LaB₆ film. The thickness of the Ag film is 150 nm to 200 nm.

A material forming the transparent conductive electrode 102 is not particularly limited, but is preferably a low work function material with a high hole injection efficiency while being transparent and use can be made of ITO or the like having a work function of 4.5 eV to 4.8 eV.

The hole transport layer 114 forming the organic layer 110 serves to efficiently move holes to the light emitting layer 116 and to suppress movement of electrons from the cathode serving as the counter electrode to the transparent conductive electrode 102 side through the light emitting layer 116, thereby enhancing the efficiency of recombination of electrons and holes in the light emitting layer 116.

Although not particularly limited, use can be made, as a material forming the hole transport layer 114, of, for example, 1,1-bis(4-di-p-aminophenyl)cyclohexane, carbazole or its derivative, triphenylamine or its derivative, or the like.

Although not particularly limited, use can be made, as the light emitting layer 116, of a quinolinol aluminum complex containing a dopant, DPVi biphenyl, or the like. Depending on use, red, green, and blue phosphors may be used by stacking them and, in a display device or the like, red, green, and blue phosphors may be used by arranging them in a matrix.

A silole derivative, a cyclopentadiene derivative, or the like can be used as the electron transport layer 118.

A non-illustrated protective layer may be provided for preventing invasion of moisture, an oxidizing gas, or the like into the light emitting layer 116. In this case, a nitride of an element selected from the group consisting of Ti, Zr, Hf, V, Nb, Ta, Cr, B, Al, and Si is preferable as a material forming the protective layer. Although the protective layer is preferably as thin as possible in terms of reducing the thermal resistance, the thickness thereof is preferably set to about 10 nm to 100 nm for preventing permeation of moisture, an oxidizing gas, or the like and more preferably 30 nm to 50 nm. In the case where the protective layer is made of the above nitride, since the thermal conductivity is high and thus the thermal resistance can be reduced, the protective layer can also serve as a heat dissipating layer. However, a heat dissipating layer may further be provided for carrying out the heat dissipation more efficiently. Aluminum, copper, or the like having a high thermal conductivity is preferable as the heat dissipating layer.

Next, a description will be given of a method of manufacturing the display element in this embodiment. A cleaned glass substrate was prepared as the transparent substrate 100 and ITO was formed into a film on the glass substrate by sputtering. The sputtering in this case may be normal sputtering, but it is preferable to use a rotary magnet sputtering apparatus.

In the film formation, the sputtering used an ITO target (preferably a sintered body of indium oxide and tin oxide). In the sputtering, Xe having a large collision sectional area was used as a plasma excitation gas, thereby generating a plasma having a sufficiently low electron temperature. The substrate temperature was set to 100° C. and the film thickness was set to 200 angstroms. Since the sputtering was carried out using the Xe plasma, the electron temperature was sufficiently low and, thus, even if the film formation was performed while irradiating Xe ions onto the ITO surface during the film formation for improving the film quality, plasma damage to the ITO film was suppressed and therefore the high-quality film formation was achieved even at a low temperature of 100° C. or less. The ITO film thus formed was patterned into a predetermined shape. The patterning was performed by photolithography. A novolak-based resist was used as a photoresist and, after carrying out exposure using a mask aligner and development using a predetermined developer, cleaning for surface organic compound removal was performed by ultraviolet irradiation for 10 minutes.

Then, using an organic film vapor deposition apparatus, the hole injection layer 112, the hole transport layer 114, the light emitting layer 116, the electron transport layer 118, and the electron injection layer 120 were continuously formed as the organic layer 110.

Then, without exposing the substrate to the atmosphere, LaB₆ and Ag were deposited as the first cathode 122 and the second cathode 124, respectively, using a rotary magnet sputtering apparatus adjacent to the organic film vapor deposition apparatus.

Referring to FIG. 2, the rotary magnet sputtering apparatus used for depositing the first and second cathodes 122 and 124 will be described.

FIG. 2 is a diagram illustrating one example of a magnetron sputtering apparatus for use in this invention, wherein the illustrated magnetron sputtering apparatus is provided with a target 1 of LaB₆ or Ag and comprises a polygonal (e.g. regular hexadecagonal) columnar rotation shaft 2, a rotary magnet group 3 in the form of helical magnetic shells helically bonded to the surface of the columnar rotation shaft 2, a fixed peripheral magnetic shell 4 disposed around the rotary magnet group 3 so as to surround them, and a peripheral paramagnetic body 5 disposed on the side opposite to the target 1 with respect to the fixed peripheral magnetic shell 4. Further, a packing plate 6 is bonded to the target 1, the columnar rotation shaft 2 and the rotary magnet group 3 are covered with a paramagnetic body 15 at their portions other than the target 1 side thereof, and further, the paramagnetic body 15 is covered with a housing 7.

The fixed peripheral magnetic shell 4 is configured to surround the rotary magnet group 3 as seen from the target 1 and, herein, is magnetized to serve as the S-pole on the target 1 side. Respective magnets of the fixed peripheral magnetic shell 4 and the rotary magnet group 3 are each in the form of a Nd—Fe—B-based sinte red magnet.

Further, a plasma shielding member 16 and the transparent substrate 100 are provided in a space 11 in an illustrated process chamber. The transparent substrate 100 has the transparent conductive electrode 102 and the organic layer 110 formed thereon and is placed on a conveyor (not illustrated) so as to move from left to right in FIG. 2.

The plasma shielding member 16 extends in the axial direction of the columnar rotation shaft 2 and defines a slit 18 that allows the target 1 to be exposed to the transparent substrate 100 side. A region not shielded by the plasma shielding member 16 (i.e. a region open to the target 1 by the slit 18) is a region where the magnetic field strength is high and a high-density plasma with a low electron temperature is generated so that there occurs no charge-up damage or ion irradiation damage to the organic layer 110 formed on the transparent substrate 1 00, and simultaneously, is a region where the film forming rate is high. By shielding a region other than this region with the plasma shielding member 16, the film formation with no damage can be carried out over a wide area without substantially reducing the film forming rate.

Further, the packing plate 6 is formed with a passage 8 for passing a coolant therethrough and an insulating member 9 is disposed between the housing 7 and an outer wall 14 forming the process chamber. A feeder line 12 connected to the housing 7 is drawn out to the exterior through a cover 13. A DC power supply, an RF power supply, and a matching unit (not illustrated) are connected to the feeder line 12.

With this structure, the plasma excitation power is supplied to the packing plate 6 and the target 1 from the DC power supply and the RF power supply through the matching unit, the feeder line 12, and the housing 7, so that a plasma is excited on the surface of the target 1. The plasma excitation is enabled only with the DC power or the RF power, but it is preferable to apply both in terms of the film quality controllability or the film forming rate controllability. The frequency of the RF power is normally selected from a range of several 100 kHz to several 100 MHz, but in terms of higher density and lower electron temperature of plasma, a higher frequency is desirable and, in this embodiment, a frequency of 13.56 MHz was used. In the sputtering, a Xe plasma was used to thereby suppress the occurrence of plasma damage to the organic layer.

### Second Embodiment

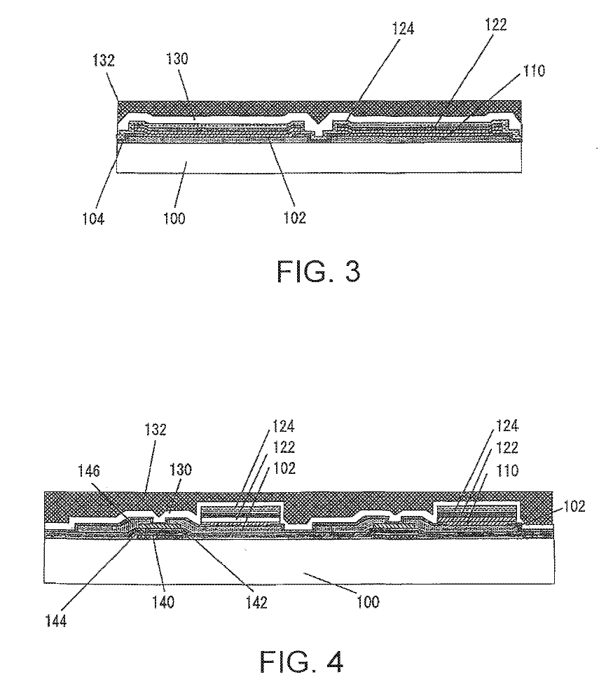

Referring to FIG. 3, a description will be given of an organic EL display device according to the second embodiment of this invention. FIG. 3 is a sectional view illustrating part of pixels of a bottom emission type passive matrix organic EL display device, which are respectively formed by organic EL elements described with reference to FIG. 1.

The illustrated organic EL display device has a structure in which a plurality of organic EL elements are arranged on a transparent substrate 100. Each organic EL element comprises a transparent conductive electrode 102 and an organic layer 110 formed on the transparent conductive electrode 102. Although not illustrated in FIG. 3, the organic layer 110 has a structure in which a hole injection layer 112, a hole transport layer 114, a light emitting layer 116, an electron transport layer 118, and an electron injection layer 120 are stacked in this order like in FIG. 1.

Further, a cathode portion comprising a first cathode 122 in the form of a LaB₆ film and a second cathode 124 in the form of an Ag film is provided on the organic layer 110. Herein, the first and second cathodes 122 and 124 are deposited by the rotary magnet sputtering apparatus illustrated in FIG. 2.

The organic EL display device further comprises a protective layer 130 formed to cover the cathode portions and a heat dissipating layer 132 formed on the protective layer 130.

Since the organic EL display device is configured such that the bottom emission type organic EL display elements shown in the first embodiment are arranged in a matrix, those elements respectively selected by the transparent conductive electrodes 102 and the cathode portions are adapted to emit light. The transparent conductive electrodes 102 and the cathode portions are patterned into a matrix so that the elements are arranged. As the protective layer 130, silicon nitride, aluminum nitride, boron nitride, or the like is preferable in terms of insulation between the different counter electrodes and, in this embodiment, use was made of silicon nitride formed by the method described in the first embodiment.

### Third Embodiment

Referring to FIG. 4, a description will be given of an organic EL display device according to the third embodiment of this invention. FIG. 4 is a sectional view illustrating part of pixels of a bottom emission type active matrix organic EL display device. The illustrated organic EL display device comprises a transparent substrate 100, a plurality of gate lines 140, a plurality of signal lines 146 intersecting the gate lines 140, and switching elements disposed at intersections of the gate lines 140 and the signal lines 146. Each switching element comprises a gate electrode 140, a gate insulating film 142 formed on the gate electrode 140, a channel region 144 of amorphous silicon formed on the gate insulating film 142, and a signal line electrode 146 formed on the channel region 144.

Further, organic EL elements illustrated in FIG. 1 are connected to the switching elements, respectively. Each organic EL element comprises a transparent conductive electrode (i.e. a pixel electrode) 102, an organic layer 110 formed on the pixel electrode 102, and first and second cathodes 122 and 124 formed on the organic layer 110 so as to be opposed to the pixel electrode 102. A protective layer 130 is formed so as to directly or indirectly cover at least the organic layers 110 and a heat dissipating layer 132 is formed so as to be in contact with the protective layer 130. In the organic layer 110, a hole injection layer, a hole transport layer, a light emitting layer, an electron transport layer, and an electron injection layer are formed in this order from the side near the pixel electrode 102, which is the same as in FIG. 1. Further, like in the first embodiment, the first and second cathodes 122 and 124 are LaB₆ and Ag films, respectively, formed by the rotary magnet sputtering apparatus.

The switching element is preferably a TFT element, an MIM element, or the like that can control ON/OFF of the current. The TFT element is preferable in terms of controllability of the brightness of the organic EL element.

Although it differs depending on a specification of a display device, a known amorphous TFT or polysilicon TFT can be suitably used as the TFT element.

Next, a description will be given of a method of manufacturing the active matrix organic EL display device in this third embodiment. At first, Al was formed into a 300 nm film by sputtering on a cleaned glass substrate. In the sputtering, an Ar, Kr, or Xe gas can be suitably used. When Xe is used, since the electron collision sectional area is large and the electron temperature is low, damage by a plasma to the formed Al film is suppressed, which is thus more preferable. Then, the formed Al film was patterned into gate lines and gate electrodes by photolithography. Then, using the dual shower plate microwave plasma film forming apparatus used in the first embodiment, silicon nitride was formed into a 300 nm film at a substrate temperature of 200° C. and at Ar:N₂:H₂:SiH₄=80:18:1.5:0.5, thereby obtaining a gate insulating film. By setting the substrate temperature to 200° C., it was possible to form a high-quality silicon nitride film having a high withstand voltage and a small interface state density and thus capable of being used as the gate insulating film.

Then, using the same apparatus, amorphous silicon was formed into a 50 nm film at a substrate temperature of 200° C. and at a volume ratio of Ar:SiH₄=95:5 and, subsequently, n+ amorphous silicon was formed into a 30 nm film at Ar:SiH₄:PH₃=94:5:1. By patterning the stacked amorphous silicon and n+ amorphous silicon films by photolithography, element regions were formed.

Then, using the same method as that shown in the first embodiment, ITO was formed into a 350 nm film and then was patterned by photolithography, thereby obtaining signal lines, signal line electrodes, and transparent conductive pixel electrodes. Then, using the patterned ITO film as a mask, the n+ amorphous silicon layer was etched by known ion etching, thereby forming TFT channel separating regions. Using the rotary magnet sputtering apparatus used in the first embodiment, a silicon nitride film was formed at room temperature, and then was subjected to patterning of organic EL element regions by photolithography, thereby obtaining a protective film at each of the TFT channel separating regions and an insulating layer for preventing a short between the transparent conductive electrode and a counter electrode of each organic EL element.

Then, using the method described in the first embodiment, the organic EL elements were formed and then the protective layer 130 and the heat dissipating layer 132 were formed in order.

### Fourth Embodiment

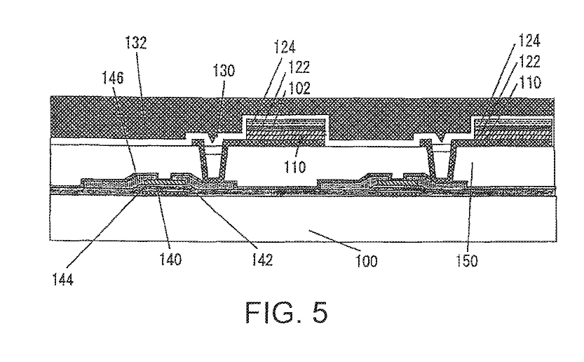

Referring to FIG. 5, a description will be given of an organic EL display device according to the fourth embodiment of this invention. The illustrated organic EL display device has a structure in which a flattening film 150 is formed on TFTs and, thereafter, organic EL elements are formed. With this structure, the organic EL elements can be formed on a flat surface and, therefore, the manufacturing yield is improved. Further, since the organic EL elements are formed at a layer different from a signal line layer 146, pixel electrodes 102 can be arranged so as to extend over the signal wiring and thus it is possible to increase an area of each light emitting element. Further, since the signal lines 146 can be formed of a material different from that of the pixel electrodes 102, it is not necessary to use a transparent conductive material and, therefore, it is possible to reduce a wiring resistance when a display device is increased in size, thereby enabling an increase in display gradation.

A bottom emission type active matrix organic EL display device of this fourth embodiment is formed in the following manner. At first, gate lines 140, TFT elements, and signal lines 146 were formed by the method described in the third embodiment. The signal lines 146 were obtained by forming Al into a 300 nm film by sputtering using a Xe gas and patterning it by photolithography. Then, a transparent photosensitive resin was coated by spin coating, then was subjected to exposure and development, and then was dried at 150° C. for 30 minutes, thereby obtaining a flattening film 150. By the above exposure and development processes, the flattening film 150 was formed with connecting holes each for connection between a pixel-side electrode of the TFT and an organic EL element.

As the transparent photosensitive resin, there is an acrylic resin, a polyolefin resin, an alicyclic olefin resin, or the like. The alicyclic olefin resin is excellent in transparency with less moisture content and release and thus is preferable and, in this embodiment, the alicyclic olefin resin was used. Then, the organic EL elements were formed in the same manner as in the first embodiment.

Hereinbelow, a description will be given of specific film forming conditions in forming a LaB₆ film by sputtering using the rotary magnet sputtering apparatus illustrated in FIG. 2.

At first, it is preferable to clean the surface of an organic layer 110 using a plasma before forming the film. For example, the appropriate cleaning conditions are 90 mTorr and RF300W with an Ar plasma. The chamber pressure during the sputtering is preferably 5 mTorr to 90 mTorr. Particularly at 50 mTorr (using an Ar plasma with an electron temperature of about 1.9 eV, the ion irradiation energy is suppressed to 10 eV or less by RF-DC combined discharge to increase the normalized ion irradiation amount to about 10), the resistivity becomes minimum (about 300 μΩcm to 400 μΩcm) and the crystallinity is improved particularly in the (100) orientation. In this event, the film forming rate is 80 nm/min. By adjusting the pressure, it is possible to suppress an increase in resistivity while increasing the film forming rate. The substrate temperature (stage temperature) may be room temperature, but if the temperature is raised, the resistivity further decreases. For example, the resistivity becomes about 175 μΩcm at a substrate temperature of 300° C.

Since the low-resistance film can be formed as described above, the LaB₆ film not only has a work function matching that of an electron injection layer, but also is practically preferable in terms of electrical conductivity as a cathode. During the sputtering, a substrate may be moved at about 1 cm/min.

While the invention made by the present inventors has been described in detail based on the embodiments, it is needless to say that this invention is not limited to those embodiments and various changes can be made within a range not departing from the gist thereof.

For example, according to this invention, it is possible to obtain not only a single organic EL element, but also an organic EL display device including a large number of organic EL elements. Further, this invention is applicable to either a passive matrix organic EL display device or an active matrix organic EL display device and, further, is applicable not only to a bottom emission type organic EL display device, but also to a top emission type organic EL display device.

What is claimed is:

1. An organic EL element, comprising:
a transparent conductive electrode;
a counter electrode opposed to said transparent conductive electrode; and
an organic layer including an organic EL light emitting layer and provided between said transparent conductive electrode and said counter electrode,
wherein said counter electrode includes a first layer of boride of a rare earth element and a second layer of a conductive and reflective material, said first layer being located on the side of said organic layer.

2. The organic EL element according to claim 1, wherein said boride of the rare earth element is LaB₆ or LaB₄.

3. The organic EL device according to claim 1, wherein said organic layer includes an electron injection layer at a portion contacting with the first layer of boride of the rare earth element, the electron injection layer having a work function of 2.5 eV to 3.0 eV.

4. The organic EL element according to claim 1, wherein the material of said second layer has a reflectivity of more than 90%.

5. The organic EL element according to claim 4, wherein the material of said second layer includes Ag.

6. The organic EL element according to claim 1, wherein said first layer has a thickness not smaller than 0.4 nm and smaller than 10 nm.

7. The organic EL element according to claim 6, wherein the thickness of said first layer is 0.5 nm to 5 nm.

8. An organic EL element, comprising:
an anode electrode;
a cathode electrode opposed to said anode electrode; and
an organic layer including an organic EL light emitting layer and provided between said anode electrode and said cathode electrode,
wherein said cathode electrode includes a layer of boride of a rare earth element having a thickness of more than 0.4 nm and less than 10 nm.

9. A method of manufacturing a light emitting element including a transparent conductive electrode formed on a transparent substrate, an organic layer including an organic EL light emitting layer and formed on the transparent conductive electrode, and a counter electrode formed on the organic layer, comprising:
upon forming the counter electrode, setting a target containing boride of a rare earth element in a sputtering apparatus having a rotary magnet, and
sputtering the target while rotating the rotary magnet, thereby forming a layer of boride of the rare earth element.

10. The method according to claim 9, wherein the target comprises LaB₆.

11. The method according to claim 9, further comprising:
forming an Ag film by sputtering after forming the layer of boride of the rare earth element, thereby forming the counter electrode.

12. The method according to claim 9, wherein the layer of boride of the rare earth element has a thickness not smaller than 0.4 nm and smaller than 10 nm.

13. An organic EL display device, comprising:
a plurality of gate lines and a plurality of signal lines arranged in a matrix;
switching elements provided at intersections of the gate lines and the signal lines; and
a plurality of organic EL elements selectively driven by the switching elements,
wherein each of the organic EL elements includes;
a transparent conductive electrode,
a counter electrode opposed to the transparent conductive electrode and including a first layer of boride of a rare earth element and a second layer of a conductive and reflective material, and
an organic layer provided between the transparent conductive electrode and the counter electrode, said first layer of said counter electrode being located on the side of said organic layer.

14. The organic EL display device according to claim 13, wherein the organic layer includes an electron injection layer at a portion contacting with the first layer of boride of the rare earth element, the electron injection layer having a work function of 2.5 eV to 3.0 eV.

15. The organic EL display device according to claim 13, wherein the boride of the rare earth element is LaB₆ or LaB₄.

16. The organic EL display device according to claim 13, wherein the material of said second layer has a reflectivity of more than 90%.

17. The organic EL display device according to claim 16, wherein the material of said second layer includes Ag.

18. The organic EL display device according to claim 13, wherein the first layer has a thickness not smaller than 0.4 nm and smaller than 10 nm.

19. The organic EL display device according to claim 18, wherein the thickness of said first layer is 0.5 nm to 5 nm.

20. An organic EL display device, comprising:
a plurality of gate lines and a plurality of signal lines arranged in a matrix;
switching elements provided at intersections of the gate lines and the signal lines; and
a plurality of organic EL elements selectively driven by the switching elements,
wherein each of the organic EL elements includes;
an anode electrode;
a cathode electrode opposed to said anode electrode including a layer of boride of a rare earth element that has a thickness of more than 0.4 nm and less than 10 nm; and
an organic layer including an organic EL light emitting layer and provided between said anode electrode and said cathode electrode.
